(19) United States
(12) Patent Application Publication
(10) Pub. No.: US 2016/0335578 A1
(43) Pub. Date: Nov. 17, 2016

(54) PROGRAM FOR CREATING WORK ASSISTANCE DATA

(71) Applicant: HITACHI, LTD, Tokyo (JP)

(72) Inventor: Hirohiko SAGAWA, Tokyo (JP)

(21) Appl. No.: 15/110,999

(22) PCT Filed: Jan. 17, 2014
(86) PCT No.: PCT/JP2014/050732

§ 371 Date: Jul. 12, 2016

(51) Int. Cl. G06Q 10/06; G06K 9/62; G06T 15/00; G06T 17/00; G05B 19/418; G06T 19/00

(52) U.S. Cl. CPC G06Q 10/06316; G06Q 10/063116; G06Q 10/067; G05B 19/41885; G06T 19/006; G06T 15/005; G06T 17/00; G06K 9/6215; G06T 2200/04; G06T 2200/08

(57) ABSTRACT

A program for creating data causes a computer to execute the following: a step of generating a converted image, which is a whole-view image the viewpoint of which has been changed, based on a 3D model generated from a plurality of whole-view images including a plurality of work targets, a step of determining the position of a work viewpoint image, which is captured from the line of sight at which work is carried out, based on the degree of similarity obtained by comparing the work viewpoint image and the converted image, and registering, onto the whole-view image, information related to a work target on which work is carried, and a step of retrieving the work viewpoint image corresponding to the registered work target based on the positional relationship of the work viewpoint image to the whole-view image, and associating the retrieved work viewpoint image with the work target.

### TECHNICAL FIELD

The present invention relates to a program and method for creating work assistance data for use in an apparatus assisting a worker carrying out various works, such as construction and maintenance and inspection of a facility.

### BACKGROUND ART

When various works, such as construction and maintenance and inspection of a facility, are carried out, a written work procedure describing the contents and sequence of the works is typically prepared. The written work procedure, which takes different forms, typically often describes the contents of work items representing individual works in accordance with a work carrying-out sequence, together with photographs and pictures showing the actual conditions, as needed (a list-form written work procedure). Following the contents of such a written work procedure, the worker can precisely complete the targeted work.

Attention has focused on the augmented reality technology that assists the user in understanding the real world by showing, at the appropriate position on the image of the real world, virtual information, such as other image and characters. The use of the augmented reality technology can show the appropriate timing, place, and contents to the worker, so that work navigation using the augmented reality technology to give an instruction to the worker is expected to be helpful for preventing human error.

To use the augmented reality technology for the work navigation, it is typically necessary to prepare 3D information (3D model) related to a space in which work is carried out (work area) and a work target, such as a meter, valve, or switch, disposed in the space, and to store data in which a work item is associated with the 3D model (augmented reality work procedure data).

As a technology that associates various information with the 3D model, Patent Literature 1 describes a technology in which the 3D model is displayed on a screen, and the position of a target is then designated by input means, such as a mouse, to associate an image or the like therewith. Patent Literature 2 describes a technology in which the 3D model is displayed to show the menu of information related to components included in the 3D model, and from the menu, the targeted component is then selected to link information related thereto.

### CITATION LIST

### Patent Literature

PTL 1: Japanese Patent Application Laid-Open No. 2010-9479

PTL 2: Japanese Patent Application Laid-Open No. 2001-356813

### SUMMARY OF INVENTION

### Technical Problem

In the above inventions, information is associated with the 3D model, but information related to a work procedure having a sequence relationship is not associated with the 3D model. To create the augmented reality work procedure data, it is necessary to easily associate the work procedure including the sequence relationship with the 3D model.

In addition, the augmented reality work procedure data is suitable for providing information to the worker using the augmented reality system, but is not suitable in order for the supervisor not using the augmented reality system to confirm the contents and flow of work, so that the conventional list-form written work procedure is considered to be suitable. Thus, the list-form written work procedure is desirably outputted from the same data as the augmented reality work procedure data.

In the above inventions, the 3D model, which is assumed to be created for the work area as precise as possible, is not easily constructed. While designing by the 3D model is now mainstream, the 3D model in designing is less likely to be matched with the state of the actual work area. Thus, the augmented reality work procedure data based on the actual work area is desirably easily created.

In addition, the list-form written work procedure is often added with an image captured from a viewpoint at which work is carried out (work viewpoint image), which is considered to be helpful in the augmented reality system, and is desirably registered to the augmented reality work procedure data. Usually, the work viewpoint image is captured at a site in which work is carried out, and is then added to the work procedure in the office, but the work viewpoint image, which notes only the particular work target, is considered to be difficult to judge to which portion of the work area the image corresponds. Thus, the work viewpoint image is desirably easily added and registered to the augmented reality work procedure data.

Further, the augmented reality work procedure data is considered to be constructed based on the contents of the existing work procedure, and in this case, each work item is desirably easily associated with the work target related thereto.

An object of the present invention is to provide a technology that can associate a work procedure including a sequence relationship with a 3D model based on the state of an actual work area, and efficiently create data capable of outputting augmented reality work procedure data and a list-form written work procedure. Another object of the present invention is to provide a technology that facilitates adding and registering a work viewpoint image to a 3D model, and registering each work item in an existing work procedure to the 3D model.

### Solution to Problem

To solve the above problems, the configurations described in the claims are employed. The present invention includes a plurality of means for solving the problems, and provides, as an example, an apparatus for creating work assistance data having an input unit that inputs a plurality of whole-view images including a plurality of work targets, a model generating unit that generates a 3D model from the inputted whole-view images, an image converting unit that generates, based on the 3D model, a deformed whole-view image, which is a whole-view image the viewpoint of which has been changed, a position designating unit that determines, based on the degree of similarity obtained by comparing the deformed whole-view image and a work viewpoint image captured from the line of sight at which work is carried out, the positional relationship of the work viewpoint image to the whole-view image, a work target registering unit that registers, onto the whole-view image, information related to a work target on which work is carried out, an associating unit that retrieves the work viewpoint image corresponding to the registered work target based on the positional relationship of the work viewpoint image to the whole-view image and associates the retrieved work viewpoint image with the work target, and a storing unit that stores the work target and the work viewpoint image associated with the work target in association with the 3D model.

The present invention also provides an information recording medium having recorded thereon a program for creating work assistance data causing a computer to execute the following: a step of generating a 3D model from a plurality of whole-view images including a plurality of work targets, a step of generating, based on the 3D model, a deformed whole-view image, which is a whole-view image the viewpoint of which has been changed, a step of determining, based on the degree of similarity obtained by comparing the deformed whole-view image and a work viewpoint image captured from the line of sight at which work is carried out, the positional relationship of the work viewpoint image to the whole-view image, a step of registering, onto the whole-view image, information related to a work target on which work is carried out, a step of retrieving the work viewpoint image corresponding to the registered work target based on the positional relationship of the work viewpoint image to the whole-view image and associating the retrieved work viewpoint image with the work target, and a step of storing the work target and the work viewpoint image associated with the work target in association with the 3D model.

### Advantageous Effects of Invention

According to the present invention, the work procedure including the sequence relationship can be associated with the 3D model based on the state of the actual work area, and the data capable of outputting the augmented reality work procedure data and the list-form written work procedure can be efficiently created.

### BRIEF DESCRIPTION OF DRAWINGS

FIG. 1 is a diagram of the configuration of a typical computer that executes programs according to an example to which the present invention is applied.

FIG. 2 is a flowchart of a process executed by a work target registering program 106.

FIG. 3 is a diagram illustrating an example of a work area.

FIG. 4 is a diagram illustrating an example of a whole-view image of the work area.

FIG. 5 is a diagram illustrating an example of the data format of a 3D model.

FIG. 6 is a diagram illustrating an example of a data format for storing the inner parameter and the outer parameter of a camera.

FIG. 7 is a diagram of assistance in explaining an example of a method for designating the position of a work target on the whole-view image.

FIG. 8 is a diagram illustrating an example of a data format for storing information related to work targets registered on the whole-view image.

FIG. 9 is a flowchart of a process executed by a new work-item adding program 108.

FIG. 10 is a diagram illustrating an example of a data format for storing work item information.

FIG. 11 is a flowchart of a process executed by a whole-view image and work viewpoint image associating program 109.

FIG. 12 is a flowchart of a process executed by a work procedure and work viewpoint image associating program 110.

FIG. 13 is a flowchart of a process executed by a work procedure sequence changing program 111.

FIG. 14 is a flowchart of a process executed by a work procedure and 3D model associating program 112.

FIG. 15 is a diagram illustrating an example of a list-form written work procedure outputted from a written work procedure output program 113.

FIG. 16 is a diagram illustrating an example of a data format for storing information related to a work procedure in 3D work procedure data.

FIG. 17 is a diagram representing the image of the 3D work procedure data.

FIG. 18 is a diagram illustrating an example of a screen for deleting and correcting an image and information.

FIG. 19 is a diagram illustrating an example in which work navigation by the augmented reality technology is executed.

FIG. 20 is a diagram illustrating an example in which the contents of the work item are superposed and displayed on the screen of a tablet computer.

### DESCRIPTION OF EMBODIMENTS

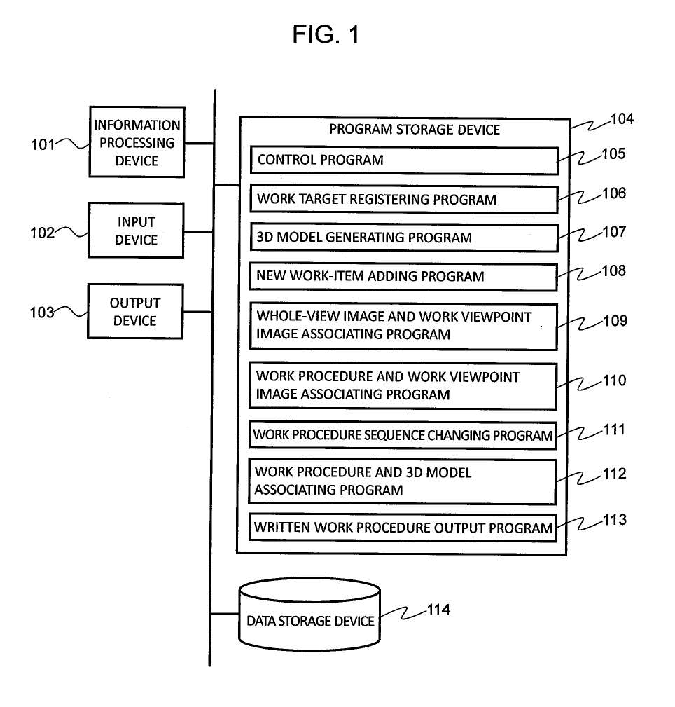

An example of the present invention will be described with reference to FIGS. 1 to 20.

FIG. 1 is a diagram of the configuration of a typical computer that executes programs according to an example of the present invention.

In FIG. 1, the reference numeral 101 denotes an information processing device that executes various programs in the present invention. An input device 102 includes a camera for inputting a whole-view image including a plurality of work targets, such as meters, valves, or switches, and a work viewpoint image captured from a viewpoint at which work is carried out, and input means with respect to the typical computer, such as a keyboard, mouse, or touch panel, in order for the user to give instructions to the programs. An output device 103 includes a monitor showing information to the user, and a printer for printing the information on a sheet, the monitor and the printer being typically used in the computer.

A program storage device 104 stores the programs in the present invention. A control program 105 controls programs 106 to 113 based on inputs from the user. The work target registering program 106 registers a plurality of whole-view images, uses the 3D model generating program 107 to obtain 3D information (3D model) of a space (work area) imaged on the whole-view images, and registers the work targets onto the whole-view images. The new work-item adding program 108 uses the whole-view image and work viewpoint image associating program 109 to determine the correspondence relationship between the work viewpoint image and the whole-view image, associates the work viewpoint image with the work target based on the determined correspondence relationship, creates a new work item including the work target and the work viewpoint image, which have been associated with each other, and adds the new work item to a work procedure.

The work procedure is refereed to as information of the form in which a plurality of work items that are information related to individual works carried out with respect to the work targets are listed according to a work carrying-out sequence. The work procedure and work viewpoint image associating program 110 retrieves the work target, such as a meter, corresponding to each work item in the previously prepared work procedure, and then associates the retrieved work target with the work item. Further, the work procedure and work viewpoint image associating program 110 retrieves the work viewpoint image corresponding to the work target based on the position on the whole-view image of the work target associated with the work item, and then associates the retrieved work viewpoint image with the work item.

The work procedure sequence changing program 111 adds sequence information to the work target on the whole-view image, and based on the added sequence information, changes the sequence number of the work item associated with the work target. The work procedure and 3D model associating program 112 associates the work item in the work procedure with the position coordinates on the 3D model based on the position of the work target on the whole-view image and the correspondence relationship between the whole-view image and the 3D model. The written work procedure output program 113 outputs information related to the work procedure associated with the 3D model, and prints a written work procedure onto a sheet. A data storage device 114 in FIG. 1 stores various data and information, such as the whole-view image, the work viewpoint image, the 3D model obtained from the whole-view images, the correspondence relationship between the whole-view image and the work viewpoint image, and information related to the work procedure.

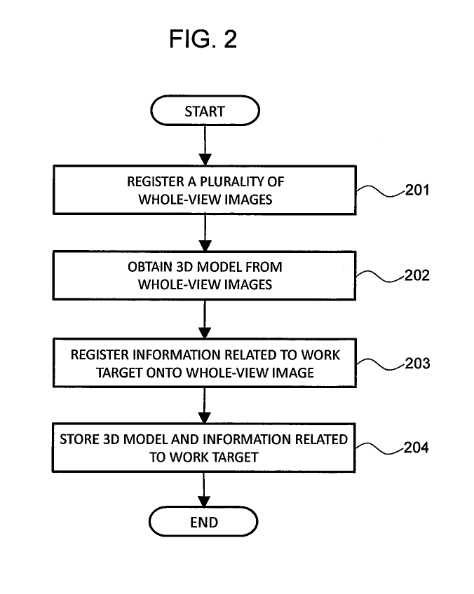

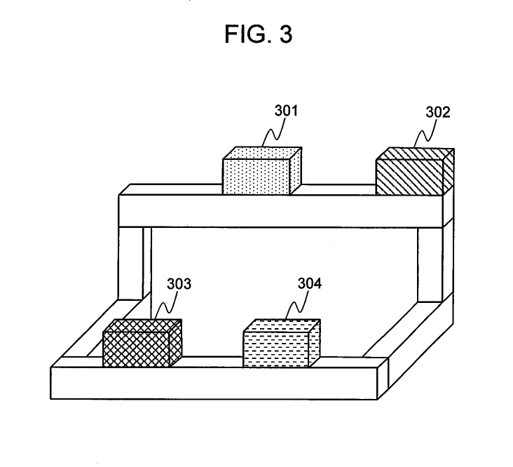

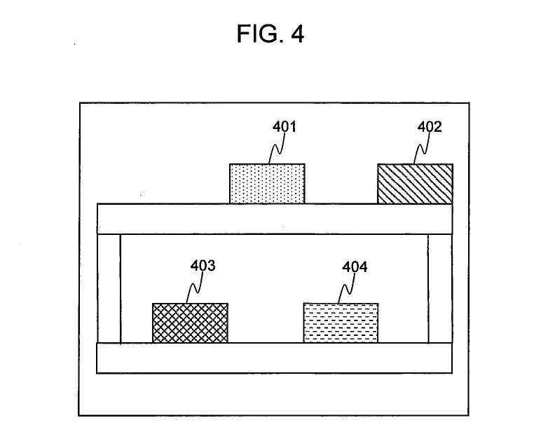

The process of the work target registering program 106 will be described with reference to FIG. 2. In step 201 in FIG. 2, a plurality of whole-view images of a work area including a plurality of work targets are registered. In the registration of the whole-view images, the user designates the whole-view images to be registered through the operation of the keyboard or mouse. FIG. 3 illustrates the configuration of the work area, and FIG. 4 illustrates its whole-view image.

The reference numerals 301, 302, 303, and 304 in FIG. 3 denote work targets disposed in a real space and actually worked by the worker, which appear as the reference numerals 401, 402, 403, and 404 on the whole-view image illustrated in FIG. 4. The whole-view images registered in step 201 are the images of the work area captured from different positions and angles. In step 202, from the whole-view images registered in step 201, the 3D information (3D model) of the work area is obtained. From a plurality of images of the same target, the targeted 3D model can be easily obtained by using well-known bundle adjustment. The use of the bundle adjustment obtains the 3D model as a set of points on the 3D space. For each image, obtained are the inner parameter of the camera, such as a focal length and the center position of the image, and the outer parameter of the camera, such as the position and direction of the camera.

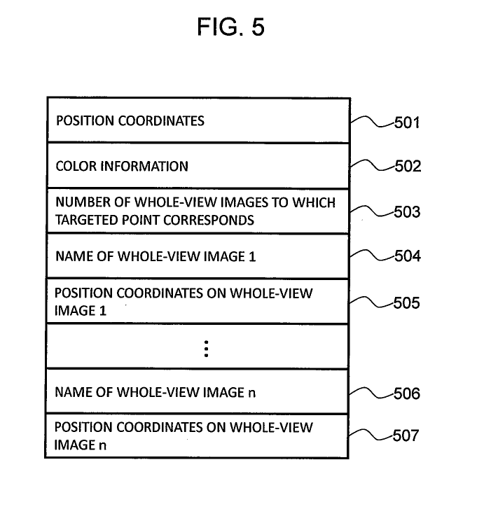

FIG. 5 illustrates an example of a data format for storing the 3D model obtained from the whole-view images. The data format in FIG. 5 includes each point constructing the 3D model, and the number of data in the data format illustrated in FIG. 5 to be stored is equal to the number of the obtained points. In FIG. 5, the reference numeral 501 denotes the position coordinates of the targeted point, and the point on the 3D space can be typically represented by a set of coordinate values with respect to the X-axis, Y-axis, and Z-axis. The reference numeral 502 denotes color information of the targeted point, and can be represented by a set of three numerical values representing the proportions of e.g., red, green, and blue components. In addition to the above method, any color representing method that is typically used can be used. Information 503 and subsequent thereof represent to which position on each whole-view image the targeted point corresponds. The reference numeral 503 denotes the number of whole-view images to which the targeted point corresponds. The reference numeral 504 denotes the name of the first whole-view image among the whole-view images to which the targeted point corresponds. The reference numeral 505 denotes the position coordinates of the targeted point on the first whole-view image. The position on the whole-view image is represented as 2D position coordinates. The reference numeral 506 denotes the name of the nth whole-view image among the whole-view images to which the targeted point corresponds. The reference numeral 507 denotes the position coordinates of the targeted point on the nth whole-view image.

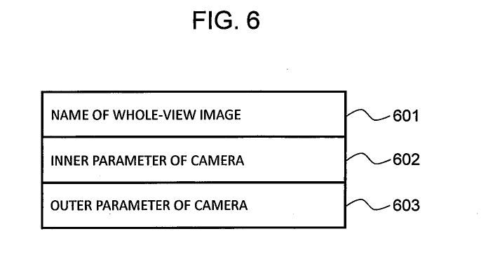

FIG. 6 illustrates an example of a data format for storing the inner parameter and the outer parameter of the camera obtained at the same time when the 3D model is obtained from the whole-view images. The inner parameter and the outer parameter of the camera are stored with respect to each whole-view image. In FIG. 6, the reference numeral 601 denotes the name of the whole-view image, the reference numeral 602 denotes the inner parameter of the camera, and the reference numeral 603 denotes the outer parameter of the camera. As described above, the inner parameter of the camera is represented by a combination of the focal length of the camera and the center position of the image. The focal length typically includes values defined with respect to the X-axis direction and the Y-axis direction of the image. The center position of the image includes the coordinate values in the X-axis direction and the Y-axis direction of the image, and the inner parameter is represented as a combination of four numerical values. The direction of the camera in the outer parameter can be represented by a rotation matrix or three numerical values representing rotation angles about the X-axis, Y-axis, and Z-axis. For the rotation matrix, the direction of the camera is typically represented by a 3×3 matrix. The position of the camera is represented by the coordinate values on the X-axis, Y-axis, and Z-axis. Thus, the outer parameter of the camera is represented as a 3×4 transformation matrix so as to include the position of the camera when the rotation matrix is used for the direction of the camera, and is represented as a combination of six numerical values when the rotation angles about the axes are used as the direction of the camera.

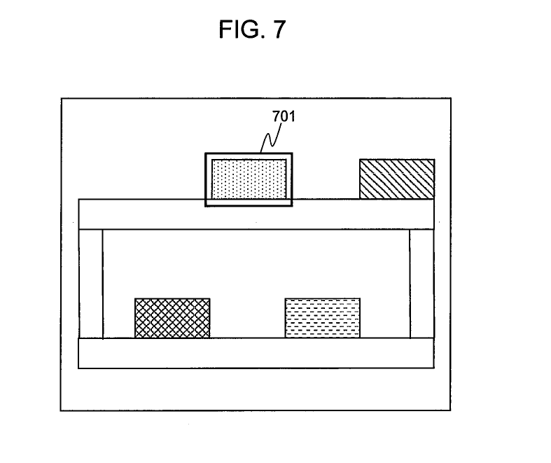

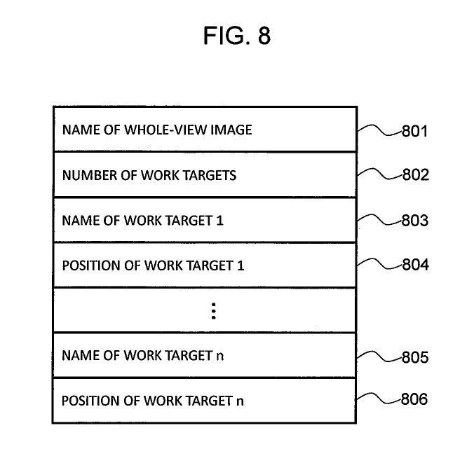

In step 203 in FIG. 2, one of the whole-view images registered in step 201 is selected to register the information related to the name and position of each work target imaged on the selected whole-view image. To designate the position of the work target, as illustrated in the reference numeral 701 in FIG. 7, the region corresponding to the work target can be designated through the operation of the keyboard or mouse. In the reference numeral 701, the region of the work target is designated by using a square, but can also be designated by a circle or any polygon. In addition, when the position of the work target is designated, the name of the work target is inputted and registered through the operation of the keyboard or mouse. In addition to the name of the work target, various information related to the work target may be registered at the same time. Further, although the work target is registered onto one of the registered whole-view images, the name or position of the work target may be registered onto all the registered whole-view images. FIG. 8 illustrates an example of a data format for storing information related to the work targets registered onto the whole-view image. In FIG. 8, the reference numeral 801 denotes the name of the whole-view image onto which the work targets are registered. The reference numeral 802 denotes the number of work targets registered onto the whole-view image. The reference numeral 803 denotes the name of the first work target. The reference numeral 804 denotes the position of the first work target. The position of the work target can be represented by a set of the position coordinates at each apex of the square or polygon on the whole-view image when the region of the position of the work target is designated by a square or any polygon, and can be represented by the center position and radius when the region of the position of the work target is designated by a circle. The reference numeral 805 denotes the name of the nth work target. The reference numeral 806 denotes the position of the nth work target.

In step 204 in FIG. 2, the 3D model obtained from the whole-view images, the parameters of the camera, and the information related to the work target registered onto the whole-view image is stored to end the process.

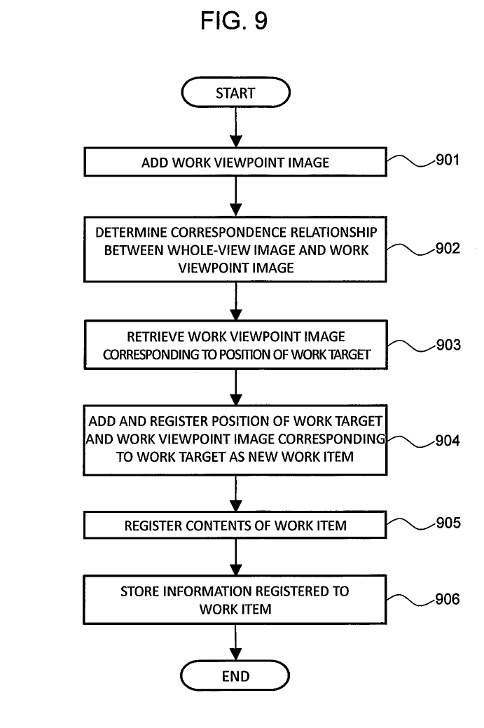

The process of the new work-item adding program 108 will be described with reference to FIG. 9. In step 901 in FIG. 9, the work viewpoint image is added. In the addition of the work viewpoint image, the user designates the work viewpoint image to be added through the operation of the keyboard, mouse or the like. In step 902, the whole-view image and work viewpoint image associating program 109 is called to determine the correspondence relationship between the whole-view image and the added work viewpoint image. The detail of the process in step 902 will be described later. In step 902, the position on the whole-view image to which the work viewpoint image corresponds is determined. The position on the whole-view image to which the work viewpoint image corresponds may be represented by position coordinates representing one point, or by a figure showing the region on the whole-view image to which the work viewpoint image corresponds. In the latter case, the region on the whole-view image to which the work viewpoint image corresponds may be represented by a circle or any polygon. The position of the work viewpoint image on the whole-view image determined in step 902 is shown on the whole-view image. In this case, the user may select, through the operation of the keyboard or mouse, whether the position of the work viewpoint image shown on the whole-view image is only for the newly added work viewpoint image or is for all the registered work viewpoint images. In step 903, the work viewpoint image corresponding to the work target is retrieved based on the determined position of the work viewpoint image on the whole-view image and the position of the work target registered by the work target registering program. For instance, this process can be performed by determining the coordinates of the center position of the region of a work target and the coordinates of the center position of the region on the whole-view image to which the work viewpoint image corresponds, and then by regarding the work viewpoint image having the center position closest to the center position of the work target, as the work viewpoint image corresponding to the work target. Alternatively, the work viewpoint image in which the distance between the center position of a work target and the center position of the work viewpoint image is present within a predetermined threshold value may be regarded as the work viewpoint image corresponding to the work target.

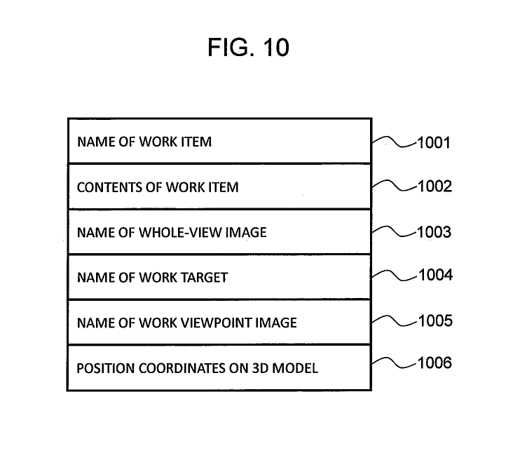

In step 904 in FIG. 9, the work item including the work target and the work viewpoint image, which are associated with each other in step 903, is generated and added to the work procedure. FIG. 10 illustrates an example of a data format for storing work item information. As the information related to the work procedure, a plurality of work items represented in the data format illustrated in FIG. 10 are listed and stored in the work carrying-out sequence. In FIG. 10, the reference numeral 1001 denotes the name of each work item, and when a new work item is added, the name of the corresponding work target can be set. Alternatively, the new work item may be inputted and added by the user through the operation of the keyboard or mouse. The name of the work item can be easily changed by the user later. The reference numeral 1002 in FIG. 10 denotes information related to the contents of the work item, and is null when the contents of the work item are newly added. This information may be added and corrected by the user through the operation of the keyboard or mouse, and may be inputted by the user when added.

The reference numeral 1003 denotes the name of the whole-view image used when the association of the work target with the work viewpoint image is determined. The reference numerals 1004 and 1005 respectively denote the name of the work target and the name of the work viewpoint image, which are associated with each other in step 903. The reference numeral 1006 denotes the position on the 3D model to which the work item corresponds, which is set by the work procedure and 3D model associating program 112 described later, and remains null here. In the date format in FIG. 10, the name of the work target 1004, the name of the work viewpoint image 1005, and the position coordinates on the 3D model 1006 are set one by one. Thus, when there are a plurality of work viewpoint images corresponding to the work target, the work viewpoint image to be registered is selected through the operation of the keyboard, mouse, or the like. Alternatively, a plurality of work viewpoint images corresponding to the work target may be registered.

In step 905 in FIG. 9, the user registers the contents of the work item, that is, the contents of the reference numeral 1002 in FIG. 10, through the operation of the keyboard, mouse, or the like. In step 906, the added contents of the work item are stored to end the process.

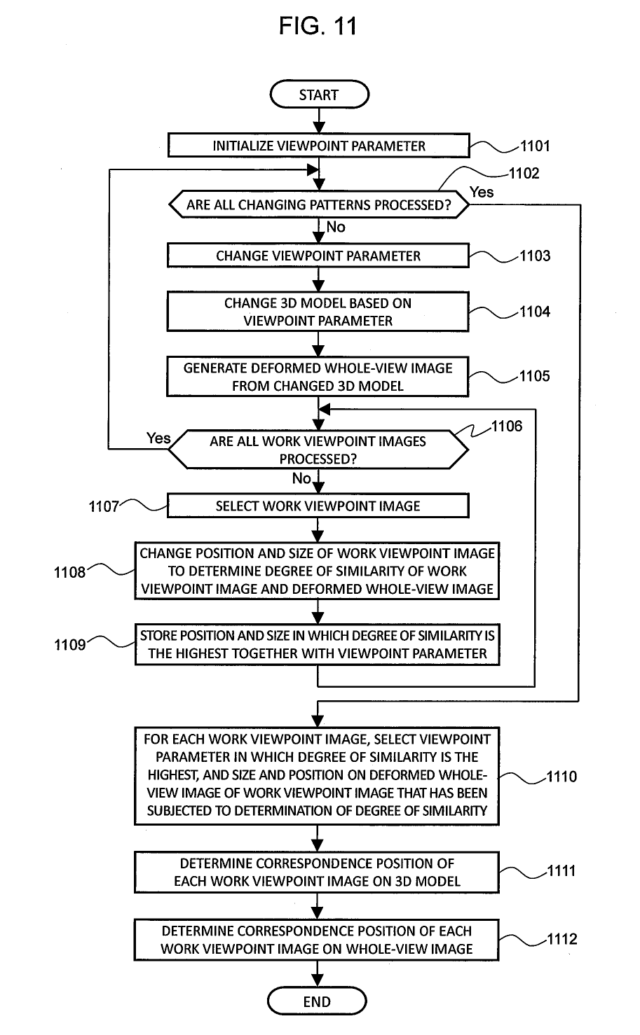

The detail of the process in step 902 in FIG. 9, that is, the process of the whole-view image and work viewpoint image associating program 109, will be described with reference to FIG. 11. In the process in step 902, the 3D model is changed to generate a deformed whole-view image, which is a whole-view image the viewpoint of which is different from the viewpoint of the whole-view image registered in step 201 in FIG. 2, and the position on the deformed whole-view image to which the work viewpoint image corresponds is determined based on the degree of similarity of the generated deformed whole-view image and the work viewpoint image, and based on the result, the position on the whole-view image registered in step 201 in FIG. 2 to which the work viewpoint image corresponds is determined.

To perform this process, a method for changing the 3D model is defined. As this method, the 3D model is changed by rotation angles about the coordinate axes and parallel movements. The present invention may use any of a plurality of methods for changing the 3D model by rotation angles about the coordinate axes. When the rotation angles about the X-axis, Y-axis, and Z-axis in the coordinate system representing the 3D model are aₓ, a_{y}, and a_{z}, and the magnitudes of the parallel movements in the axis directions are tₓ, t_{y}, and t_{z}, the 3D model can be changed, as expressed by Equation 1. In Equation 1, (x, y, z, 1)^{T} is the position coordinate of the point on the unchanged 3D model, and (X, Y, Z)^{T} is the position coordinate of the point on the changed 3D model.

$$[ Equation 1 ]$$

$$( \begin{matrix}X \\ Y \\ Z\end{matrix} ) = ( \begin{matrix}{r}_{11} & {r}_{12} & {r}_{13} & {t}_{x} \\ {r}_{21} & {r}_{22} & {r}_{23} & {t}_{y} \\ {r}_{31} & {r}_{32} & {r}_{33} & {t}_{z}\end{matrix} ) ( \begin{matrix}x \\ y \\ z \\ 1\end{matrix} ) = ( \begin{matrix}cos {a}_{x} cos {a}_{y} & \begin{matrix}cos {a}_{x} sin {a}_{y} sin {a}_{z} - \\ sin {a}_{x} cos {a}_{z}\end{matrix} & \begin{matrix}cos {a}_{x} sin {a}_{y} cos {a}_{2} + \\ sin {a}_{x} sin {a}_{z}\end{matrix} & {t}_{x} \\ sin {a}_{x} cos {a}_{y} & \begin{matrix}sin {a}_{x} sin {a}_{y} sin {a}_{z} + \\ cos {a}_{x} cos {a}_{z}\end{matrix} & \begin{matrix}sin {a}_{x} sin {a}_{y} cos {a}_{z} - \\ cos {a}_{x} sin {a}_{z}\end{matrix} & {t}_{y} \\ - sin {a}_{y} & cos {a}_{y} sin {a}_{z} & cos {a}_{y} cos {a}_{z} & {t}_{z}\end{matrix} ) ( \begin{matrix}x \\ y \\ z \\ 1\end{matrix} )$$

In the process in step 902, using, as a parameter, six numerical values representing the rotation angles about the coordinate axes and the parallel movements, the 3D model is changed. In the following description, the parameter including the six numerical values is called a viewpoint parameter.

In step 1101 in FIG. 11, the viewpoint parameter is initialized. Here, assuming that each numerical value in the viewpoint parameter is changed within a predetermined range, and in step 1101, as each numerical value of the viewpoint parameter, a predetermined lower-limit value is set. In addition to this method, known are a method in which natural characteristic amounts of the whole-view image and the work viewpoint image are extracted to determine, from the correspondence relationship therebetween, the rotation angles and the parallel movements of the 3D model, and a method in which the rotation angles and the parallel movements of the 3D model are determined by using the values obtained from a separate sensor, and these methods may be used to initialize the viewpoint parameter.

In step 1102, whether the process of step 1103 and subsequent thereof is executed to all the patterns of the previously prepared viewpoint parameter is checked, and when there are any unprocessed patterns, the routine goes to step 1103. In step 1103, the viewpoint parameter is changed so as to have the pattern of each unprocessed viewpoint parameter. In step 1104, based on the viewpoint parameter set in step 1103, the position coordinates of each point constructing the 3D model are changed by Equation 1. In step 1105, from the changed 3D model, the deformed whole-view image is generated. The position (sₓ, s_{y}, 1)^{T} on the 2D image to which the point (X, Y, Z)^{T} on the 3D model corresponds can be calculated by using the inner parameter of the camera by Equation 2. In Equation 2, fₓ is the focal length of the camera in the X-axis direction, f_{y} is the focal length of the camera in the Y-axis direction, and (cₓ, c_{y}) is the coordinate of the center position of the image. In addition, k is a size factor.

$$k ( \begin{matrix}{s}_{x} \\ {s}_{y} \\ 1\end{matrix} ) = ( \begin{matrix}{f}_{x} & 0 & {c}_{x} \\ 0 & {f}_{y} & {c}_{y} \\ 0 & 0 & 1\end{matrix} ) ( \begin{matrix}X \\ Y \\ Z\end{matrix} ) \qquad [ Equation 2 ]$$

When all the whole-view images registered in step 201 in FIG. 2 are imaged by the same camera, the inner parameters of the camera determined in step 202 are all the same. When the whole-view images are imaged by different cameras, the inner parameters are likely to be different. In this case, the inner parameter used for generating the deformed whole-view image is the average value of the inner parameters determined in step 202. In step 1105, the correspondence positions on the 2D image of all the points on the 3D model changed in step 1104 are determined, and at the positions, the points using the color information related to the original points are plotted, thereby generating the deformed whole-view image.

In step 1106, whether the process in step 1107 and subsequent thereof with respect to the generated deformed whole-view image is performed to all the work viewpoint images is checked. When there are any unprocessed work viewpoint images, the routine goes to step 1107. In step 1107, one of the unprocessed work viewpoint images is selected. In step 1108, determined is the degree of similarity of the work viewpoint image selected in step 1107 and the deformed whole-view image generated in step 1105. The degree of similarity is calculated based on the values of the overlapped pixels of the work viewpoint image and the deformed whole-view image, which are overlapped with each other. The typically used evaluation scale, such as the sum of squared difference and the correlation coefficient of the values of the pixels, can be calculated as the degree of similarity. In addition, in the calculation of the degree of similarity, the overlapping is performed while the size of the work viewpoint image and the position of the work viewpoint image overlapped on the deformed whole-view image are changed.

Thus, the degree of similarity is determined for each combination of the size and the position on the deformed whole-view image of the work viewpoint image. In step 1109, from among the degrees of similarity determined in step 1108, the highest degree of similarity and the size and the position on the deformed whole-view image of the work viewpoint, which have the highest degree of similarity, are selected so as to be stored together with the viewpoint parameter. From the process in steps 1107 to 1109, determined for each work viewpoint image are the size and the position on the deformed whole-view image of the work viewpoint image in which the degree of similarity of the work viewpoint image and the deformed whole-view image is the highest. In step 1106, when there are no unprocessed work viewpoint images, the routine returns to step 1102.

In step 1102, when it is judged that the process is performed to all the patterns of the viewpoint parameters, the routine goes to step 1110. In step 1110, selected for each work viewpoint image are the viewpoint parameter in which the degree of similarity of the work viewpoint image and the whole-view image is the highest, and the size and the position on the deformed whole-view image of the work viewpoint image. In step 1111, based on the viewpoint parameter, the size and the position on the deformed whole-view image of the work viewpoint image, which are selected in step 1110, to which position on the unchanged 3D model the contents of the work viewpoint image correspond is determined. The deformed whole-view image is generated by changing each point on the 3D model by Equation 1, and then by using Equation 2 to convert the point on the changed 3D model to each point on the 2D image. Thus, the point correspondence relationships before and after the conversion by Equations 1 and 2 are stored to facilitate, from the position on the deformed whole-view image, the determination of the position on the 3D model before the 3D model is changed by Equation 1.

In step 1111, listed are the position coordinates on the deformed whole-view image overlapped with each work viewpoint image when the degree of similarity is determined from the size and the position on the deformed whole-view image of the work viewpoint image, which are stored for the work viewpoint image, and based on the correspondence relationship between each point on the deformed whole-view image and each point on the 3D model, the position coordinates on the 3D model corresponding to the listed position coordinates on the deformed whole-view image are listed. The listed points on the 3D model have spatial spread, so that the center position or the center of gravity position of the listed points on the 3D model is the position on the 3D model to which the work viewpoint image corresponds. Alternatively, a rectangular parallelpiped including the listed points on the 3D model may be determined so that information representing the determined rectangular parallelpiped, such as the position coordinates of the apexes of the rectangular parallelpiped, is the position on the 3D model corresponding to the work viewpoint image. Further, a set of the listed points on the 3D model may be associated with the work viewpoint image. Furthermore, when the position coordinates on the deformed whole-view image corresponding to the work viewpoint image are listed, not the position coordinates corresponding to the entire work viewpoint image, for instance, the position coordinates on the deformed whole-view image corresponding to the region within a predetermined range from the center of the work viewpoint image may be listed. Alternatively, from color information, contour information, and characteristic amount information, the region judged to be the work target on the work viewpoint image may be extracted to list only the position coordinates on the deformed whole-view image corresponding to the extracted region. Further, the user may designate the region on the work viewpoint image through the operation of the keyboard or mouse, and then list the position coordinates on the deformed whole-view image corresponding to the designated region.

Finally, in step 1112, based on the position on the 3D model determined in step 1111, to which position on the whole-view image the work viewpoint image corresponds is determined. The correspondence relationship between the position coordinates of the points on the 3D model and the position coordinates on each whole-view image is calculated when the 3D model is obtained from the whole-view images, as described above, so that the correspondence position on the whole-view image can be easily determined from the position on the 3D model. The position on the whole-view image to which the work viewpoint image corresponds may be represented by the position coordinates of a particular point, or may be represented as the region on the whole-view image to which the work viewpoint image corresponds, by a circle or a polygon.

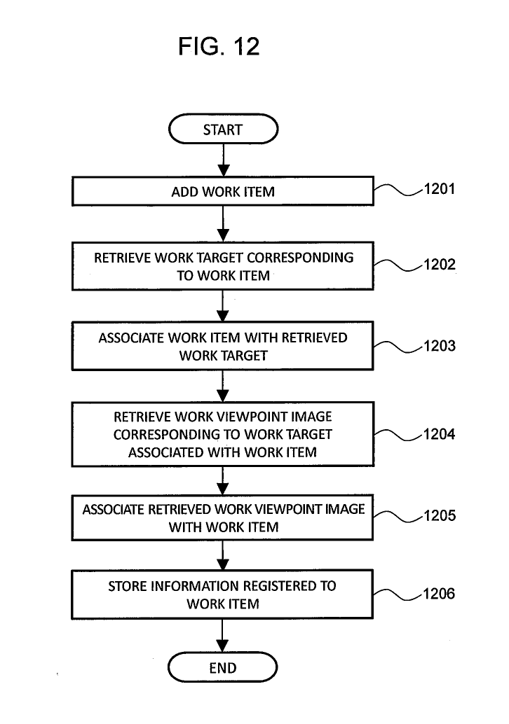

The process of the work procedure and work viewpoint image associating program 110 will be described with reference to FIG. 12. In step 1201 in FIG. 12, the work item in the previously prepared work procedure is added. In the addition of the work item, the user designates the work item to be added through the operation of the keyboard or mouse. The work item to be added in step 1201 is the information including the name of the work item 1001 and the contents of the work item 1002 in the data format of the information related to the work items illustrated in FIG. 10. In step 1202, from among the work targets registered onto the whole-view image, the work target corresponding to the added work item is retrieved.

Whether the work item corresponds to the work target can be judged depending on whether the name of the work target is included in the name and the contents of the work item. Alternatively, a set of keywords with respect to the work target may be separately stored to designate the work target corresponding to the work item depending on whether the corresponding keyword is included in the name and the contents of the work item.

In step 1203, when the work target corresponding to the work item is retrieved, the retrieved work target is associated with the work item. Specifically, in the data format of the information related to the work item in FIG. 10, the name of the retrieved work target is registered to the reference numeral 1004. When there are a plurality of retrieved work targets, the work target to be registered may be selected and registered by the user through the operation of the keyboard or mouse, or the names of the work targets may be registered to the reference numeral 1004. In step 1204, the work viewpoint image corresponding to the work target associated with the retrieved work item is retrieved. Since in step 902 in FIG. 9, the correspondence position on the whole-view image is determined, the position on the whole-view image to which the work target is registered and the position on the whole-view image to which the work viewpoint image corresponds are used to select the work viewpoint image in which the distance between both is the shortest, or the work viewpoint image in which the distance between both is less than a predetermined threshold value, thereby retrieving the work viewpoint image corresponding to the work target.

In step 1205, the retrieved work viewpoint image is associated with the work item. Specifically, in the data format of the information related to the work item in FIG. 10, the name of the retrieved work viewpoint image is registered to the reference numeral 1005. When there are a plurality of retrieved work viewpoint images, the work viewpoint image to be registered may be selected and registered by the user through the operation of the keyboard or mouse, or the names of the work viewpoint images may be registered to the reference numeral 1005. In step 1206, the contents of the work item are stored to end the process. In the above process, the work viewpoint image is not included in the work item to be added. When the work viewpoint image is included in the work item to be added, the whole-view image and work viewpoint image associating program 109 is used to determine the position on the whole-view image to which the work viewpoint image included in the work item corresponds, and the work target corresponding to the work viewpoint image is retrieved to associate the work item, the work target, and the work viewpoint image with each other. Alternatively, both the process using the name and the contents of the work item and the process using the work viewpoint image included in the work item may be executed, and from the results of the processes, the corresponding retrieved work target may be associated with the work item.

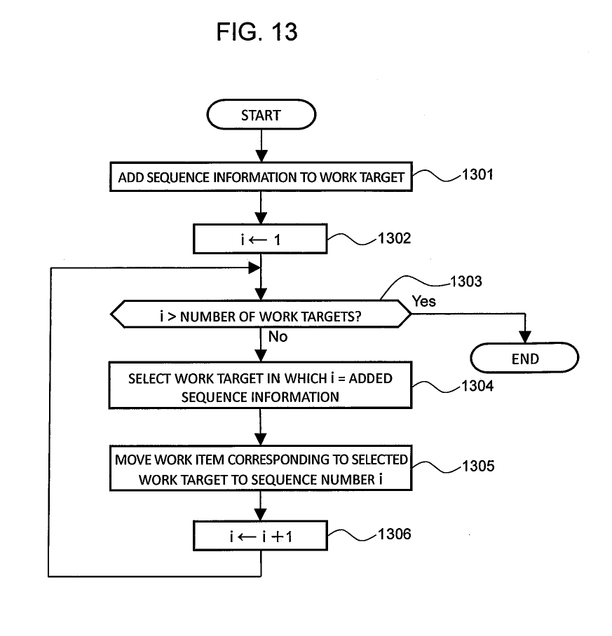

The process of the work procedure sequence changing program 111 will be described with reference to FIG. 13. In step 1301 in FIG. 13, sequence information is added to the work target registered onto the whole-view image. The addition of the sequence information is performed based on the operation of the keyboard and mouse by the user. As the sequence information, numerical values or symbols representing the sequence are used. In step 1302, numerical value 1 is substituted into variable i. In step 1303, whether the value of variable i is smaller than the number of work targets added with the sequence information is checked. When the value of variable i is equal to or smaller than the number of the corresponding work targets, the routine goes to step 1304. In step 1304, the work target added with the sequence information corresponding to the value of variable i is retrieved and selected from the work targets registered onto the whole-view image. For instance, when i=1, the work target added with the sequence information representing that it is listed first is selected, and when i=2, the work target added with the sequence information representing that it is listed second is selected. In step 1305, the work item associated with the selected work target is retrieved from the work procedure to move to the place with the sequence number shown by the value of variable i. In step 1306, 1 is added to the value of variable i to return to step 1303. In step 1303, when the value of variable i is larger than the number of work targets added with the sequence information, the process is ended.

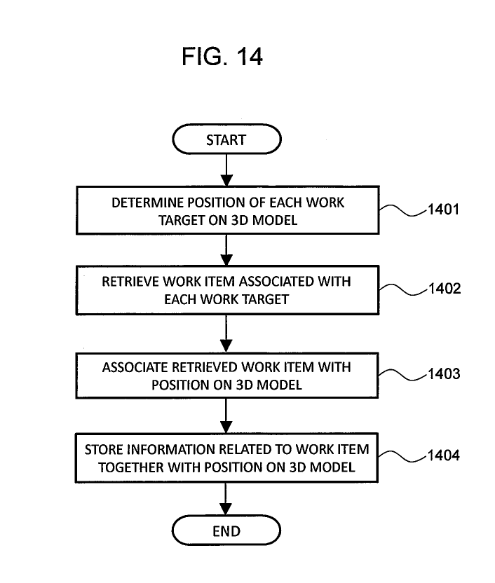

The process of the work procedure and 3D model associating program 112 will be described with reference to FIG. 14. In step 1401 in FIG. 14, the position of each work target on the 3D model is determined. As described above, the correspondence relationship between the position coordinates on the whole-view image and the position coordinates on the 3D model is calculated when the 3D model is obtained from the whole-view images, and in step 1401, the position coordinates on the 3D model corresponding to the region on the whole-view image corresponding to the work target are listed. The listed points on the 3D model have spatial spread, so that the center position or the center of gravity position of the listed points on the 3D model is the position on the 3D model corresponding to the work target. Alternatively, a rectangular parallelpiped including the listed points on the 3D model may be determined so that information representing the determined rectangular parallelpiped, such as the position coordinates at the apexes of the rectangular parallelpiped, is the position on the 3D model corresponding to the work target.

In step 1402, the work item associated with each work target is retrieved. This can be easily performed by checking the name of the work target 1004 in the data format of the information related to the work items illustrated in FIG. 10. In step 1403, with the position on the 3D model determined with respect to the work target, the work item corresponding to the work target is associated. Specifically, the position coordinates on the 3D model obtained in step 1401 are registered to the position coordinates on the 3D model 1006 in the data format of the information related to the work items illustrated in FIG. 10. In step 1404, the contents of the work item are stored to end the process.

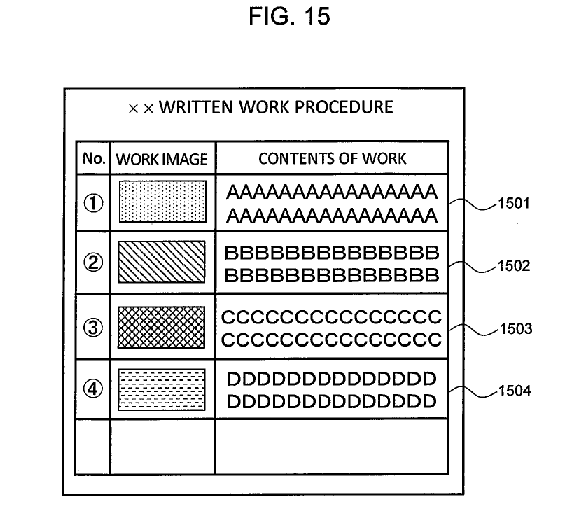

In a state where the work target, the work viewpoint image, and the position on the 3D model are associated with each work item in the work procedure, the written work procedure output program 113 is executed to output information related to the list-form written work procedure and the work procedure associated with the 3D model (3D work procedure data). FIG. 15 illustrates an example of the list-form written work procedure outputted from the written work procedure output program 113. The reference numerals 1501, 1502, 1503, and 1504 in FIG. 15 denote work items, and the sequence, the work viewpoint images, and the contents of works are shown. The list-form written work procedure can be obtained by extracting the necessary information from among the information related to the work items illustrated in FIG. 10, e.g., the name of the work item 1001, the contents of the work item 1002, and the name of the work viewpoint image 1005 to convert the necessary information to a predetermined layout and form, thereby printing the necessary information according to the registered sequence. A plurality of layouts used at printing may be prepared so that the user can select one of them at printing through the operation of the keyboard or mouse. The user may select the information related to the work item to be printed through the operation of the keyboard or mouse. The 3D work procedure data includes the information related to the work procedure and the 3D model.

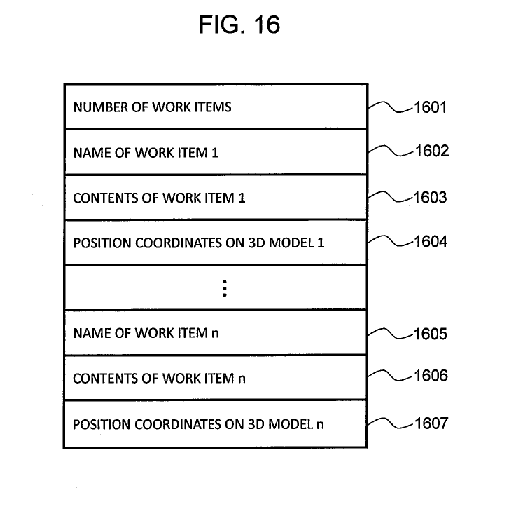

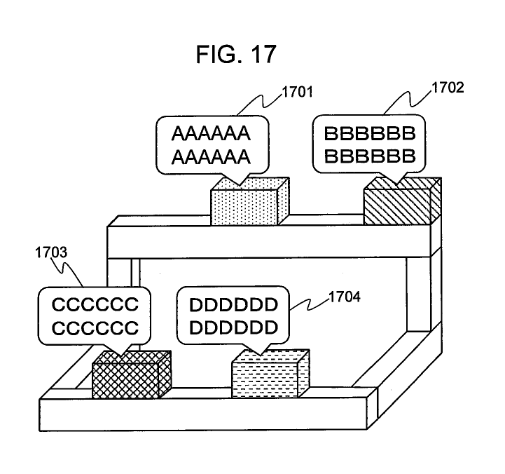

FIG. 16 illustrates an example of a data format for storing information related to the work procedure in the 3D work procedure data. In FIG. 16, the reference numeral 1601 denotes the number of work items, the reference numeral 1602 denotes the name of the first work item, the reference numeral 1603 denotes the contents of the first work item, and the reference numeral 1604 denotes the position coordinates on the 3D model to which the first work item corresponds. The reference numeral 1605 denotes the name of the nth work item, the reference numeral 1606 denotes the contents of the nth work item, and the reference numeral 1607 denotes the position coordinates on the 3D model to which the nth work item corresponds. The reference numerals 1602 and 1605 correspond to the reference numeral 1001 in the data format of the information related to the work items illustrated in FIG. 10, the reference numerals 1603 and 1606 correspond to the reference numeral 1002, and the reference numerals 1604 and 1607 correspond to the reference numeral 1006. That is, the information related to the work procedure in the 3D work procedure data is created by extracting the information related to the reference numerals 1001, 1002, and 1006, from the information related to the work items stored in the data format illustrated in FIG. 10. Alternatively, the information related to the work procedure in the 3D work procedure data may be extracted so as to include the name of the work target 1004 and the name of work viewpoint image 1005. The 3D model in the 3D work procedure data is the same as the 3D model obtained from the whole-view images. Thus, the 3D work procedure data is outputted as the data of the image as illustrated in FIG. 17. FIG. 17 illustrates the image in a state where work items 1701, 1702, 1703, and 1704 are associated with the work area in FIG. 3, and in the actual 3D work procedure data, the work items 1701, 1702, 1703, and 1704 are stored in association with the position coordinates on the 3D model. In addition, in FIG. 17, the information related to the sequence of the work items is not illustrated.

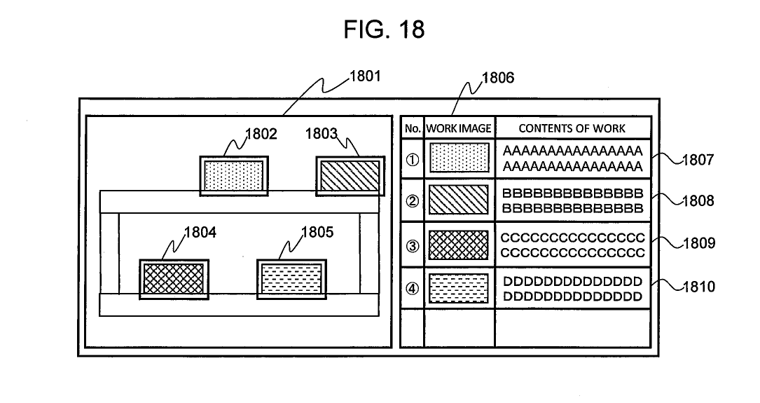

The process for adding the information related to the whole-view image, the work viewpoint image, and the work procedure has been described above, but by applying the typical user interface technology of the computer to the control program 105 in FIG. 1, the user can delete and correct the added image and information. For instance, the screen disposed as illustrated in FIG. 18 can be displayed on the screen of the computer. In FIG. 18, the reference numeral 1801 denotes a region displaying the whole-view image, and as indicated by the reference numerals 1802, 1803, 1804, and 1805, the positions of the work targets registered onto the whole-view image are superposed and displayed on the whole-view image. The reference numeral 1806 denotes a region displaying the work procedure, and the reference numerals 1807, 1808, 1809, and 1810 denote information related to the work items, the contents of the work items being displayed on the right side of the work viewpoint images. The use of the typical user interface technology of the computer enables the user to operate the keyboard or mouse on the screen as illustrated in FIG. 18 for selecting the work target and the contents of the work procedure, and deleting and correcting their image and information. Although not illustrated in FIG. 18, a menu and a button for designating the operation executed by the user can be disposed around the reference numerals 1801 and 1806.

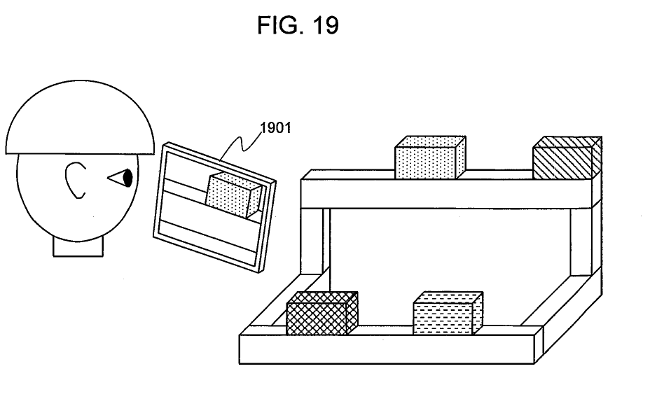

FIG. 19 illustrates an example in which the 3D work procedure data outputted from the example in the present invention is used to execute work navigation by the augmented reality technology. The augmented reality technology assists the user in understanding the real world by showing, at the appropriate position on the image of the real world, virtual information, such as other image and characters. FIG. 19 illustrates an example in which as an input/output device for the user, a tablet computer 1901 having, on its back surface thereof, a camera is used, and in addition to this, a head mount display with a camera or a mobile computer may be used. When the work navigation is performed in the form illustrated in FIG. 19, the work area is captured by the camera of the tablet computer 1901, and then, the image of the work area is displayed on the screen of the computer. Further, the computer aligns the captured image of the work area with the 3D model in the 3D work procedure data. To align the image of the work area with the 3D model, a method for disposing a marker having a special shape and pattern in the work area to calculate the positional relationship between the marker and the camera has been well-known. By previously aligning the marker with the 3D model, it is possible to calculate which part of the 3D model is imaged in the image of the work area. As a result of the aligning of the image of the work area with the 3D model, when there is a portion with which the work item is associated on the image of the work area, the contents of the corresponding work item are superposed and displayed on the image of the work area.

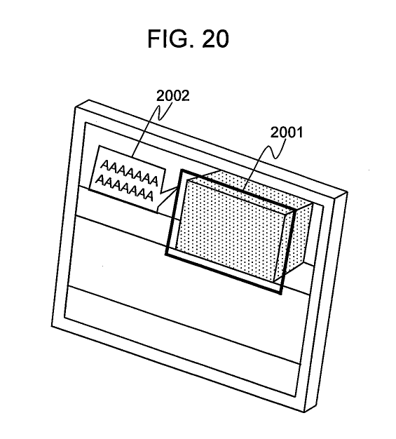

FIG. 20 illustrates an example in which the contents of the work item are superposed and displayed on the screen of the tablet computer. In FIG. 20, the reference numeral 2001 denotes a portion with which the work item is associated, and the reference numeral 2002 denotes the contents of the work item. In FIG. 20, the work item is assumed to be associated with the region on the 3D model having spatial spread, such as the region corresponding to the work target, and on the screen illustrated in FIG. 20, the region on the 3D model is converted to the region on the 2D image, and is shown by a square, as indicated by the reference numeral 2001. Further, in FIG. 20, the contents of the work item indicated by the reference numeral 2002 are related to and displayed at the position with which the contents of the work item are associated. The contents of the work item may be displayed at a predetermined position, such as the upper left side of the screen. Since the work items have the sequence relationship, the untargeted work item can be prevented from being displayed even when the position with which the untargeted work item is associated is present on the image of the work area. Alternatively, the information related to the untargeted work item can be displayed by the user through the operation of the keyboard or mouse.

From the above, a program for creating work assistance data described in this example includes a step of generating a 3D model from a plurality of whole-view images including a plurality of work targets, a step of generating, based on the 3D model, a deformed whole-view image, which is a whole-view image the viewpoint of which has been changed, a step of determining, based on the degree of similarity obtained by comparing the deformed whole-view image and a work viewpoint image captured from the line of sight at which work is carried out, the positional relationship of the work viewpoint image to the whole-view image, a step of registering, onto the whole-view image, information related to a work target on which work is carried out, a step of retrieving the work viewpoint image corresponding to the registered work target based on the positional relationship of the work viewpoint image to the whole-view image and associating the retrieved work viewpoint image with the work target, and a step of storing the work target and the work viewpoint image associated with the work target in association with the 3D model.

Needless to say, an information recording medium that records this program is within the scope of the technological idea of the present invention.

By employing this configuration, the data that can output the augmented reality work procedure data and the list-form written work procedure can be efficiently created.

### REFERENCE SIGNS LIST

101: Information processing device,
102: Input device,
103: Output device,
104: Program storage device,
105: Control program,
106: Work target registering program,
107: 3D model generating program,
108: New work-item adding program,
109: Whole-view image and work viewpoint image associating program,
110: Work procedure and work viewpoint image associating program,
111: Work procedure sequence changing program,
112: Work procedure and 3D model associating program,
113: Written work procedure output program,
114: Data storage device,
1901: Tablet computer.

1. An information recording medium having recorded thereon a program causing a computer to execute the following:
a step of generating a 3D model from a plurality of whole-view images including a plurality of work targets;
a step of generating, based on the 3D model, a deformed whole-view image, which is a whole-view image the viewpoint of which has been changed;
a step of determining, based on the degree of similarity obtained by comparing the deformed whole-view image and a work viewpoint image captured from the line of sight at which work is carried out, the positional relationship of the work viewpoint image
to the whole-view image;
a step of registering, onto the whole-view image, information related to a work target on which work is carried out;
a step of retrieving the work viewpoint image corresponding to the registered work target based on the positional relationship of the work viewpoint image to the whole-view image and associating the retrieved work viewpoint image with the work target; and
a step of storing the work target and the work viewpoint image associated with the work target in association with the 3D model.

2. The information recording medium according to claim 1, further comprising:
at retrieving the work viewpoint image associated with the work target, a step of adding, to a work procedure that is information in which a plurality of work items that are information representing the contents of work are listed in accordance with a work carrying-out sequence, the retrieved work viewpoint image and the work target, as a new work item; and
a step of registering the information representing the contents of the work to the added work item.

3. The information recording medium according to claim 2, further comprising:
a step of retrieving the related work item from the contents of the previously stored work procedure based on the information related to the registered work target to associate the retrieved work item with the work target on the whole-view image;
a step of retrieving the work viewpoint image corresponding to the work target with which the work item is associated, based on the positional relationship of the work viewpoint image to the whole-view image; and
a step of associating the retrieved work viewpoint image with the work item.

4. The information recording medium according to claim 1, further comprising:
a step of displaying the position of the work viewpoint image on the whole-view image based on the positional relationship of the work viewpoint image to the whole-view image.

5. The information recording medium according to claim 2, further comprising:
a step of adding sequence information to the registered work target; and
a step of correcting the sequence number of the work item in the work procedure based on the sequence information.

6. The information recording medium according to claim 1, further comprising:
a step of determining the position of the work target on the 3D model based on the correspondence relationship between the whole-view image and the 3D model; and
a step of storing the information related to the work target or the contents of work item corresponding to the work target in association with the determined position of the work target.

7. An apparatus for creating data comprising:
an input unit that inputs a plurality of whole-view images including a plurality of work targets;
a model generating unit that generates a 3D model from the inputted whole-view images;
an image converting unit that generates, based on the 3D model, a deformed whole-view image, which is a whole-view image the viewpoint of which has been changed;
a position designating unit that determines, based on the degree of similarity obtained by comparing the deformed whole-view image and a work viewpoint image captured from the line of sight at which work is carried out, the positional relationship of the work viewpoint image to the whole-view image;
a work target registering unit that registers, onto the whole-view image, information related to a work target on which work is carried out;
an associating unit that retrieves the work viewpoint image corresponding to the registered work target based on the positional relationship of the work viewpoint image to the whole-view image and associates the retrieved work viewpoint image with the work target; and
a storing unit that stores the work target and the work viewpoint image associated with the work target in association with the 3D model.

8. The apparatus according to claim 7, further comprising:
a sequence changing unit that at retrieving the work viewpoint image associated with the work target, adds, to a work procedure that is information in which a plurality of work items that are information representing the contents of work are listed in accordance with a work carrying-out sequence, the retrieved work viewpoint image and the work target, as a new work item; and
an item adding unit that registers the information representing the contents of the work to the added work item.

9. The apparatus according to claim 8,
wherein the item adding unit retrieves the related work item from the contents of the work procedure stored in the storing unit based on the information related to the registered work target to associate the retrieved work item with the work target on the whole-view image, retrieves the work viewpoint image corresponding to the work target with which the work item is associated, based on the positional relationship of the work viewpoint image to the whole-view image, and associates the retrieved work viewpoint image with the work item.

10. The apparatus according to claim 8,
wherein the sequence changing unit adds sequence information to the registered work target, and corrects the sequence number of the work item in the work procedure based on the sequence information.

11. The apparatus according to claim 8,
wherein the item adding unit determines the position of the work target on the 3D model based on the correspondence relationship between the whole-view image and the 3D model, and stores the information related to the work target or the contents of the work item corresponding to the work target in association with the determined position of the work target.
